(19) United States
(12) Patent Application Publication
(10) Pub. No.: US 2006/0043556 A1
(43) Pub. Date: Mar. 2, 2006

(54) Stacked packaging methods and structures

(76) Inventors: Chao-Yuan Su, Koahsiung (TW); Pei-Haw Tsao, Tai-chung (TW); Chender Huang, Hsin-Chu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/925,488

(22) Filed: Aug. 25, 2004

(51) Int. Cl. H01L 23/02

(52) U.S. Cl. 257/686

(57) ABSTRACT

A packaging method and structures are disclosed. A first die is mounted on a package substrate. A chip scale package is mounted on the first die. The chip scale package comprises a chip scale package substrate and a second die mounted on a first surface of the chip scale package substrate. A third die is mounted on a second surface of the chip scale package substrate. Accordingly, the height of the stacked package can be reduced.

### FIELD OF THE INVENTION

The present invention relates to packaging methods and structures and, more particularly relates to stacked packaging methods and structures.

### BACKGROUND OF THE INVENTION

The need for increased memory capacity with a smaller footprint has led to development of stacked packages and packaging techniques. Stacked packages generally allow smaller, thinner packages. For many years, new package form factors have allowed size reduction in both the length and width (X and Y dimensions) of packages. More recently, there has been an increased interest in reducing the height (Z dimension). Increased use of portable devices, such as the exponential grown in wireless communications has increased the need for even more dramatic height (Z dimension) reduction. To meet these challenges, stacked packaging has been achieved, typically by stacking two or more die within a single package.

Stacked packages allow more semiconductor functions per unit of area of board space and more semiconductor functions per unit of volume of application space, as well as significant size and weight reductions. Including two or more die in one package decreases the number of components mounted on a given printed circuit board. Stacked packages provide a single package for assembly, test and handling which reduces package cost.

Stacked packages also allow a low overall cost without requiring cutting edge technology, because a desired set of functions can be included within the stacked package without having to put all of the functions in a single IC chip. Also, because die-to-die interconnects can be made within the package, the package I/O and the printed circuit board (PCB) routing are simplified. Because multiple dies are included with the footprint of a single stacked package, the length and/or width of the PCB can be reduced.

FIG. 1 is a cross sectional view showing a prior art stacked package.

A digital circuit die 110 is mounted on a package substrate 100 by using an adhesive layer 105. The digital circuit die 110 is wire bonded to the package substrate 100. An analog circuit die 120 is mounted on the digital circuit die 110 by using an adhesive layer 115. A chip scale package (CSP) 130 is mounted above the analog die 120 using an adhesive layer 135. The CSP 130 is a land grid array (LGA) package. The analog circuit die 120 is also wire bonded to the package substrate 100. In order to provide a clearance to wire bond the analog circuit die 120, a spacer layer 140 is used to separate the analog circuit 120 and a chip scale package (CSP) 130. The CSP 130 is then wire bonded to the package substrate 100. An encapsulation layer 150 covers the stacked structure, including the digital circuit die 110, the analog circuit die 120, the spacer 140 and the CSP 130, for preventing physical impacts from outside and particles. Solder balls 160 are provided under the package substrate 160 for providing mechanical and electrical connections between the stacked package and a printed circuit board (not shown).

In order to wire bond the analog circuit die 120 to the substrate 100, the spacer layer 140 is necessarily required, or the CSP 130 would contact the analog circuit die 120 and interfere with the wires 121 that connect the die 120 to the package substrate 100. Due to the use of the spacer layer 140, the height of the stacked package increases. In addition, the CSP 130 is not evenly supported by the spacer layer 140. This can lead to warpage of the CSP 130. Also, the wires 121 of the analog circuit die 120 are in the same region as the wires 111 of the digital circuit die 110, and these wired can become short circuited. Further, while wire bonding the CSP 130 to the package substrate 100, a wire bonding force is applied to the location A shown in FIG. 1. The mechanical force may flip the CSP 130 and result in destruction of the stacked structure.

U.S. Patent Application Publication No. 2004/0124518 discloses a semiconductor stacked multi-package module (MPM) which has an inverted second package and an electrically shielded first package. According to that patent publication, z-interconnection between the stacked packages in the MPM is wire bond based, and an upper package is inverted. Generally, the patent publication features various configurations of various stacked packages, including a bottom (lower) package and at least one inverted top (upper) package, and methods for stacking and interconnecting the various packages by wire-bonding based z-interconnection.

U.S. Patent Application Publication No. 2004/0046239 discloses a stacked package for integrated circuits. The space-saving integrated circuit package employs two printed circuit boards joined together. The upper board has an integrated circuit attached by flip-chip technology and the lower board has a cavity for holding an integrated circuit that is located beneath the upper integrated circuit. The lower integrated circuit is bonded to the bottom of the upper board below the upper integrated circuit and electrically connected to wiring on the lower surface of the lower board by wire bond connections.

An improved stacked packaging method and structure is desired.

### SUMMARY OF THE INVENTION

Some embodiments include a packaging method. A first die is mounted on a package substrate. A chip scale package is mounted on the first die. The chip scale package comprises a substrate and a second die mounted on a first surface of the substrate. A third die is mounted on a second surface of the substrate.

Some embodiments include a stacked package. The stacked package comprises a first die, a chip scale package and a third die. The first die is mounted on a package substrate. The chip scale package is mounted on the first die. The chip scale package comprises a substrate and a second die mounted on a first surface of the substrate. The third die is mounted on a second surface of the substrate.

Some embodiments include another stacked package. The stacked package comprises a first die, a chip scale package and a third die. The first die is mounted on a package substrate by a bump. The chip scale package is mounted on the first die by a first adhesive layer. The chip scale package is wire bonded to the package substrate. The chip scale package comprises a substrate and a second die which is wire bonded to a first surface of the substrate. The third die is mounted on a second surface of the substrate by a second adhesive layer, and wire bonded to the second surface of the substrate.

The above and other features of the present invention will be better understood from the following detailed description of the preferred embodiments of the invention that is provided in connection with the accompanying drawings.

### BRIEF DESCRIPTION OF THE DRAWINGS

FIG. 1 is a cross sectional view showing a prior art stacked package.

FIG. 2 is a schematic cross sectional view showing an exemplary stacked package according to one embodiment of the present invention.

FIG. 3 is a schematic cross sectional view showing another exemplary stacked package.

### DETAILED DESCRIPTION OF THE INVENTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

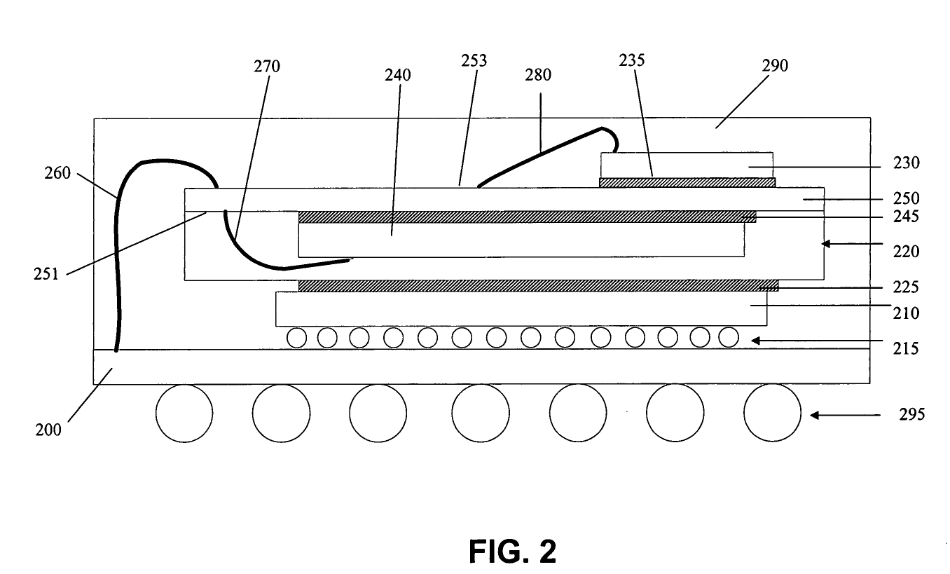

FIG. 2 is a schematic cross sectional view showing an exemplary stacked package according to one embodiment of the present invention.

The stacked package comprises a package substrate 200, a first die 210, a package 220 and a third die 230. The first die 210 is flip-chip mounted on the package substrate 200. The package 220 is mounted on the first die 210. The third die 230 is die attached on the second surface 253 of the chip scale package substrate 250 of package 220. The package 220 comprises a second die 240 and a chip scale package substrate 250. The second die 240 is mounted on a first surface 251 of the chip scale package substrate 250. The third die 230 is thus mounted on a second surface 253 of the chip scale package substrate 250, opposite the second die 240.

The first die 210 can be, for example, an application-specific integrated circuit (ASIC) which has an active face with a plurality of contact pads, each contact pad having a respective solder bump 215 thereon. The exemplary ASIC, i.e. the first die 210, is flip-chip mounted to the package substrate 200 by reflowing the solder bumps 215. The first die 210 can be mounted to the substrate 200 by, for example, a ball grid package (BGA) method or a plastic ball grid package (PBGA) method. In some embodiments, the first die 210 is an area array die which is encapsulated in a chip scale package. The first die 210 is not limited to being an ASIC die, and any die capable of being wire bonded to the substrate 200 may be used.

The package 220 can be any type of package adapted to be wire bonded to the package substrate 200, for example, a chip scale package, a land grid array package or the other package which is mounted on the first die 210 by using an adhesive layer 225. The adhesive layer 225 can be a material such as epoxy or the other material that adheres the first die 210 to the package 220. The package 220 is flipped so as to provide the second surface 253 of the chip scale package substrate 250 for the mounting of the third die 230.

The third die 230 can be, for example, an analog device which is mounted on the second surface 253 of the chip scale package substrate 250 by using an adhesive layer 235. The adhesive layer 235 can be a material such as epoxy or the other material that adheres the package 220 to the third die 230. In some embodiments, the third die 230 can be, for example, an area array die which is encapsulated in a chip scale package. The third die 230 is not limited to being an analog die, and any die capable of being wire bonded to the substrate 200 may be used.

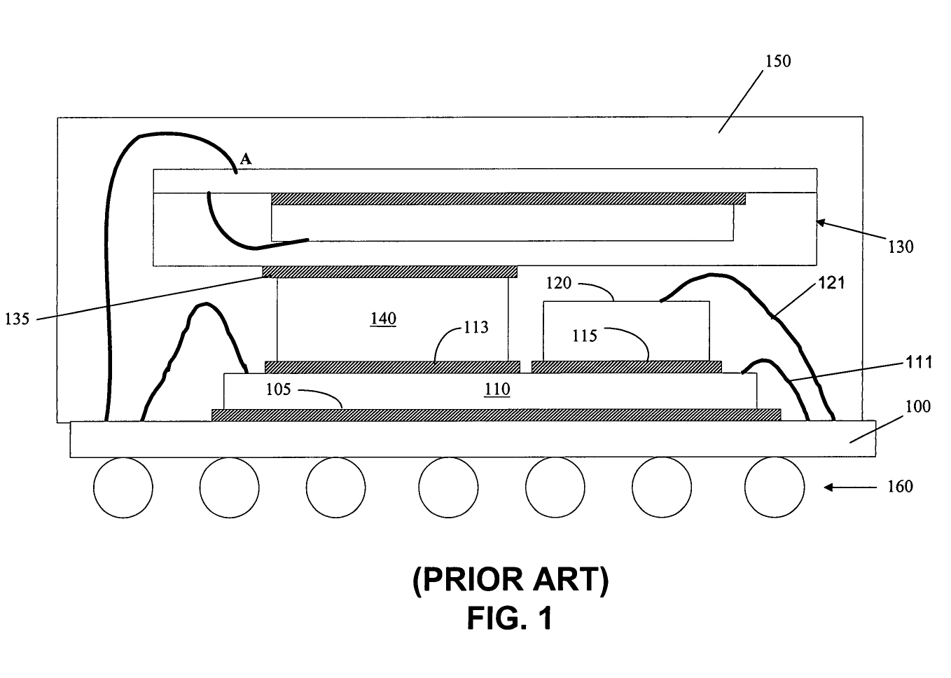

In this embodiment, the package 220 is wire bonded to the package substrate 200 through the gold wires 260. In the exemplary embodiment, the package 220 is a land grid array (LGA) package. An LGA chip scale package (CSP) 220 is a package without any terminations (solder balls) on the bottom. Instead, the LGA package 220 has tiny round gold plated pads on the bottom (top surface in the orientation of FIGS. 1 and 2), similar to a ball grid array (BGA) package without BGA balls soldered to each pad. The. LGA package 220 includes an LGA package substrate 250, and the second die 240 wire bonded to the first surface 251 of the LGA package substrate 250 using gold wires 270. Wire bonding techniques are well known to those skilled in the art, and a description thereof is not included herein. In this embodiment, the second die 240 is die bonded to the first surface 251 of the chip scale package substrate 250 by using a die attach adhesive layer 245. The adhesive layer 245 may be a material such as epoxy or the other material that can provide adhesion for the second die 240 and the chip scale package substrate 250.

In some embodiments, the second die 240 can be mounted to the chip scale package substrate 250 by a flip chip method, using an array of solder bumps to connect contact pads on the active face of the second die 240 to contact pads of the chip scale package substrate 250. Wires 270 are not used if die 240 is flip chip mounted. One of ordinary skill understands that the flip chip method results in a more compact package 220. Though a small height of the package 220 is preferred, the package 220 with a slightly larger height may be used as long as the height of the package 220 does not substantially affect the stacked package. In this embodiment, the third die 230 is wire bonded to the second surface 253 of the chip scale package substrate 250 through the wire 280.

Referring to FIG. 2, an encapsulation layer 290 covers the first die 210, the package 220 and the third die 230. The encapsulation layer 290 can be a resin material such as epoxy resin for protecting the first die 210, the package 220 and the third die 230 from external physical impacts or particles. In this embodiment, solder balls 295 are formed under the package substrate 200 for electrically contacting a printed mother board or other printed circuit board.

Due to the arrangement of this embodiment, the height of the stacked package is substantially reduced so as to be molded in a mini-molded cap. The arrangement of FIG. 2 eliminates the need for the spacer 140 that was used in the configuration of FIG. 1. The height of the package of FIG. 2 can be reduced (relative to the configuration of FIG. 1) by an amount that is approximately equal to the difference between the height of the spacer 140 and the height of the analog circuit die 120. Thus, a thinner stacked module package is possible using the configuration and method of FIG. 2. In one example, the package of FIG. 1 has a height of approximately 1.4 mm, and the package of FIG. 2 has a height of approximately 1.3 mm.

Although the exemplary ASIC 210 is flip chip mounted, in other embodiments, in which the package 220 has a smaller length and width than the ASIC 210, and all of the contact pads of ASIC 210 are exposed about the perimeter of the ASIC 210, the ASIC may also be wire bonded.

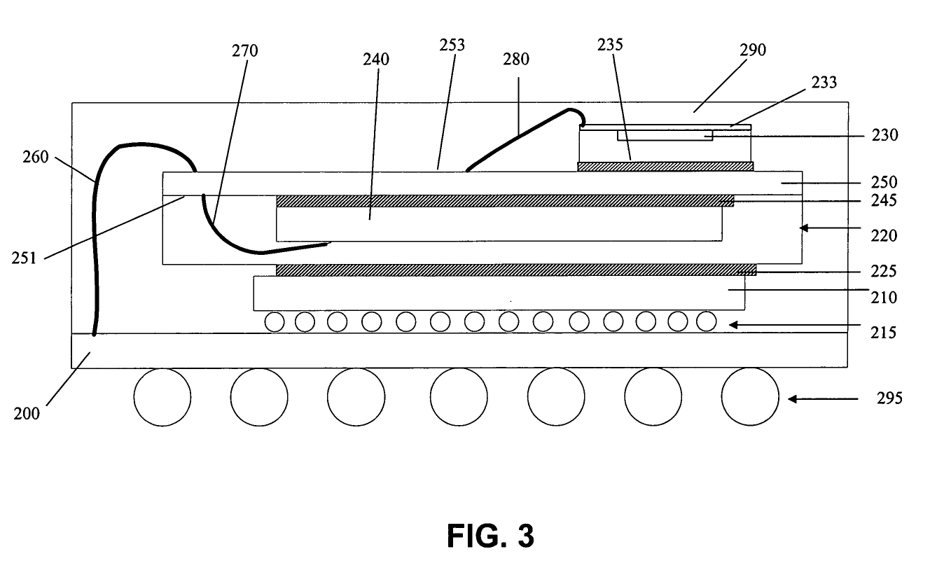

FIG. 3 is a schematic cross sectional view showing another stacked package with an additional chip scale package.

Except for the package substrate 233, items in FIG. 3 that are the same as items in FIG. 2 are indicated by the same reference numerals. Detailed descriptions of these items are not repeated. In this embodiment, the third die 230 is an area array die which is mounted on the package substrate 233 and encapsulated as a CSP. The chip scale package substrate 250 is wire bonded to the package substrate 233. As described above, the concern of the height of the stacked package maybe is compensated by the other factors, such as electrical performance or particle issues. According to these factors, the CSP with the third die 230 may be deposited over the package 220.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A packaging method, comprising:
mounting a first die on a package substrate;
mounting a chip scale package on the first die, the chip scale package comprising a chip scale package substrate and a second die mounted on a first surface of the substrate; and
mounting a third die on a second surface of the substrate.

2. The packaging method of claim 1, wherein the step of mounting a first die on the package substrate comprises a flip chip mounting step.

3. The packaging method of claim 1, wherein the step of mounting the chip scale package on the first die comprises using an adhesive layer.

4. The packaging method of claim 3, further comprising wire bonding the chip scale package to the package substrate.

5. The packaging method of claim 1, wherein the step of mounting the third die on the chip scale packaging comprises using an adhesive layer.

6. The packaging method of claim 5, further comprising wire bonding the third die to the second surface of the chip scale package substrate.

7. The packaging method of claim 1, further comprising wire bonding the second die to the first surface of the chip scale package substrate.

8. The packaging method of claim 1, wherein the first die or the third die is an area array die.

9. The packaging method of claim 1, further comprising encapsulating the first die, the chip scale package and the second die.

10. The packaging method of claim 1, wherein the chip scale package is a land grid array package.

11. A stacked package, comprising:
a first die mounted on a package substrate;
a chip scale package mounted on the first die, the chip scale package comprising a chip scale package substrate and a second die mounted on a first surface of the chip scale package substrate; and
a third die mounted on a second surface of the chip scale package substrate.

12. The stacked package of claim 11, wherein the first die is flip-chip mounted to the package substrate.

13. The stacked package of claim 11, further comprising an adhesive layer between the chip scale package and the first die.

14. The stacked package of claim 13, wherein the chip scale package is wire bonded to the package substrate.

15. The stacked package of claim 11, further comprising an adhesive layer between the third die and the second surface of the chip scale package substrate.

16. The stacked package of claim 15, wherein the third die is wire bonded to the second surface of the chip scale package substrate.

17. The stacked package of claim 11, wherein the second die is wire bonded to the first surface of the chip scale package substrate.

18. The stacked package of claim 11, further comprising an encapsulant covering the first die, the chip scale package and the third die.

19. The stacked package of claim 11, wherein the first die or the third die is an area array die.

20. The stacked package of claim 11, wherein the chip scale package is a land grid array package.

21. A stacked package, comprising
a first die flip chip mounted on a package substrate;
a chip scale package mounted on the first die by a first adhesive layer, the chip scale package wire bonded to the package substrate, the chip scale package comprising a substrate and a second die wire bonded to a first surface of the substrate; and
a third die mounted over a second surface of the substrate by a second adhesive layer, and wire bonded to the second surface of the substrate.

22. The stacked package of claim 21, wherein the first die or the third die is an area array die.

23. The stacked package of claim 21, further comprising an encapsulant covering the first die, the package and the third die.
